(19) United States
(12) Patent Application Publication
(10) Pub. No.: US 2025/0221171 A1
(43) Pub. Date: Jul. 3, 2025

(54) LIGHT EMITTING DISPLAY DEVICE

(71) Applicant: LG Display Co., Ltd., Seoul (KR)

(72) Inventors: Dae-Hee KIM, Paju-si (KR); Moon-Soo KIM, Paju-si (KR)

(73) Assignee: LG Display Co., Ltd., Seoul (KR)

(21) Appl. No.: 18/951,603

(22) Filed: Nov. 18, 2024

(30) Foreign Application Priority Data
Dec. 28, 2023 (KR) 10-2023-0194004

(51) Int. Cl. H10K 59/122; H10K 59/12; H10K 59/80

(52) U.S. Cl. CPC H10K 59/122; H10K 59/1201; H10K 59/80515; H10K 59/80521

(57) ABSTRACT

A light emitting display device includes: a substrate including a plurality of subpixels; a bank formed along a boundary of a subpixel, among the plurality of subpixels, the bank including a first opening; a first electrode in the first opening and on the bank; a light emitting layer on the first electrode and disposed inside the first electrode; a protective pattern which has an insulating property, covers edges of the first electrode and the light emitting layer, and includes a second opening corresponding to the first opening; and a second electrode in the second opening and on the protective pattern.

### CROSS REFERENCE TO RELATED APPLICATION

The present application claims the priority benefit of Korean Patent Application No. 10-2023-0194004, filed in Republic of Korea on Dec. 28, 2023, which is hereby incorporated by reference in its entirety for all purposes as if fully set forth herein.

### BACKGROUND

### Field

The present disclosure relates to a light emitting display device and a method of manufacturing the same.

### Discussion of the Related Art

Recently, flat panel display devices having excellent characteristics such as thinness, light weight, and low power consumption have been widely developed and applied to various fields.

Among the flat panel display devices, a light emitting display device including a light emitting element such as a light emitting diode is a display device in which charges are injected into a light emitting layer formed between an anode and a cathode to form pairs of electrons and holes, and then the pairs disappear to emit light.

In general, an anode of a light emitting element is formed as a structure covered by a bank, and in this case, a problem occurs that a light emitting layer deteriorates inward, shrinking a light emission region.

### SUMMARY

An advantage of the present disclosure is to provide a light emitting display device and a method of manufacturing the same that can improve shrinkage of a light emission region due to deterioration of a light emitting layer progressing inward.

Additional features and advantages of the present disclosure will be set forth in the description which follows, and in part will be apparent from the description, or may be learned by practice of the disclosure. These and other advantages of the present disclosure may be realized and attained by the structure particularly pointed out in the written description and claims hereof as well as the appended drawings.

To achieve these and other advantages and in accordance with the purpose of the present disclosure, as embodied and broadly described herein, a light emitting display device includes: a substrate including a plurality of subpixels; a bank formed along a boundary of a subpixel, among the plurality of subpixels, the bank including a first opening; a first electrode in the first opening and on the bank; a light emitting layer on the first electrode and disposed inside the first electrode; a protective pattern which has an insulating property, covers edges of the first electrode and the light emitting layer, and includes a second opening corresponding to the first opening; and a second electrode in the second opening and on the protective pattern.

In another aspect, a method of manufacturing a light emitting display device includes: forming a bank on a substrate including a plurality of subpixels, the bank being arranged along a boundary of a subpixel, among the plurality of subpixels, and including a first opening; forming a first electrode in the first opening and on the bank; forming a light emitting layer on the first electrode and inside the first electrode; forming a protective pattern having an insulating property, covering edges of the first electrode and the light emitting layer, and including a second opening corresponding to the first opening; and forming a second electrode in the second opening and on the protective pattern.

It is to be understood that both the foregoing general description and the following detailed description are by way of example and are intended to provide further explanation of the disclosure as claimed.

### BRIEF DESCRIPTION OF THE DRAWINGS

The accompanying drawings, which are included to provide a further understanding of the present disclosure and are incorporated in and constitute a part of this specification, illustrate embodiments of the present disclosure and together with the description serve to explain the principles of the disclosure. In the drawings:

FIG. 1 is a plan view schematically illustrating a light emitting display device according to an example embodiment of the present disclosure;

FIG. 2 is a plan view schematically illustrating a plan structure of a subpixel of FIG. 1.

FIG. 3 is a cross-sectional view taken along a line III-III′ of FIG. 1; and

FIGS. 4 to 23 are views schematically illustrating a method of manufacturing a light emitting display device according to an example embodiment of the present disclosure.

### DETAILED DESCRIPTION

Advantages and features of the present disclosure, and implementation methods thereof, will be clarified through following example embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Further, the protected scope of the present disclosure is defined by scopes of claims and their equivalents.

A shape, a size, a ratio, an angle, and a number disclosed in the drawings for describing embodiments of the present disclosure are merely examples, and thus, the present disclosure is not limited to the illustrated details. The same reference numerals refer to the same components throughout the description unless otherwise specified.

Furthermore, in the following description, where the detailed description of the relevant known function or configuration may unnecessarily obscure the subject matter of the present disclosure, the detailed description of such known function or configuration may be omitted. Where ‘comprising’, ‘including’, ‘having’, ‘consisting’, and the like are used in the present disclosure, one or more other parts can be added unless a more limiting term like ‘only’ is used. The terms of a singular form may include plural forms, and vice versa, unless otherwise specified.

In construing an element described herein, the element should be construed as including an error margin or range even if there is no separate explicit description.

In the case of a description of a positional relationship, for example, where the positional relationship of two parts is described as ‘on’, ‘over’, ‘above’, ‘below’, ‘beside’, ‘under’, and the like, one or more other parts can be positioned between such two parts unless a more limiting term, such as ‘right’ or ‘directly,’ is used.

In the case of a description of a temporal relationship, for example, where a temporal precedence is described as ‘after’, ‘following’, ‘before’, and the like, cases that are not continuous can be included unless a more limiting term, such as ‘directly’ or ‘immediately,’ is used.

In describing components of the present disclosure, terms such as “first,” “second,” and the like may be used. These terms are intended merely to identify the corresponding components separately from the other components, and are not intended to define or limit the essence, order, sequence, or number of the corresponding components.

Respective features of various embodiments of the present disclosure can be partially or wholly connected to or combined with each other and can be technically interlocked and driven variously as those skilled in the art may sufficiently understand, and respective embodiments can be independently implemented from each other or can be implemented together in a co-dependent relationship.

Hereinafter, example embodiments of the present disclosure are described in detail with reference to the drawings. In the following description, the same and like reference numerals may be assigned to the same and like components, and redundant descriptions thereof may be omitted.

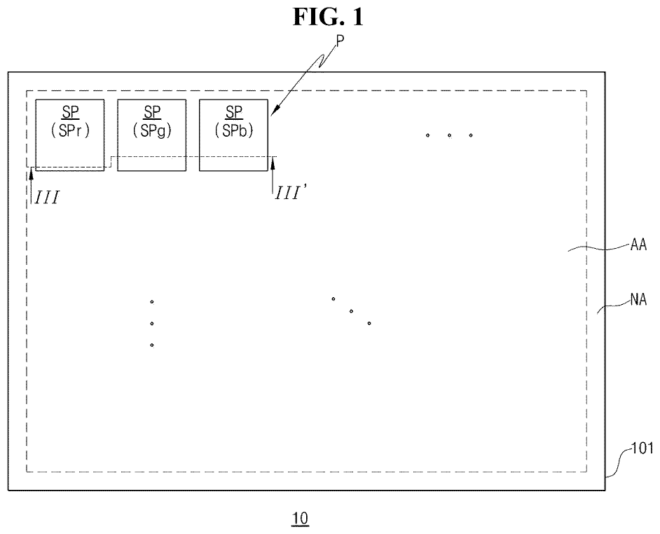

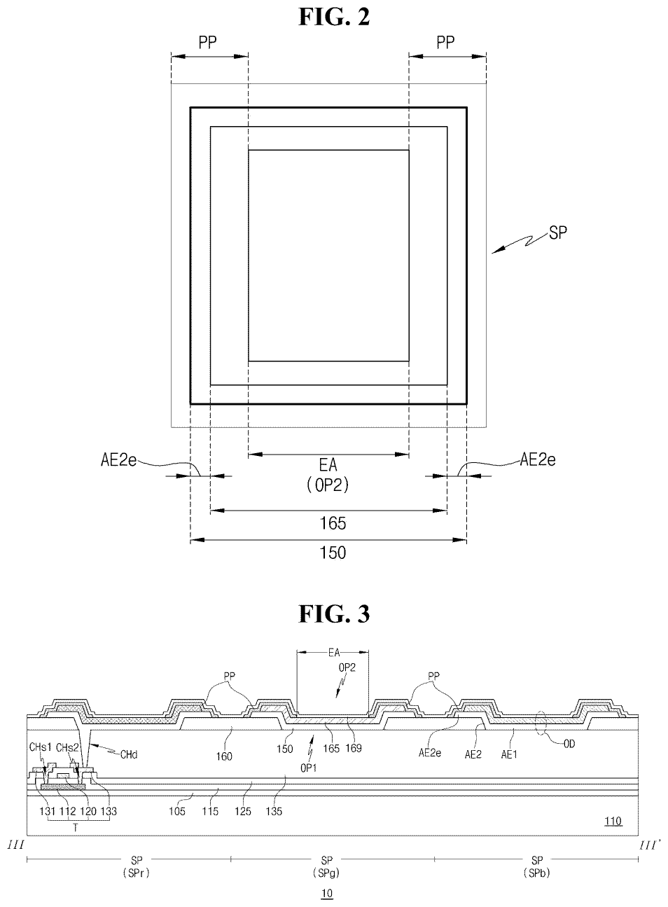

FIG. 1 is a plan view schematically illustrating a light emitting display device according to an example embodiment of the present disclosure. FIG. 2 is a plan view schematically illustrating a plan structure of a subpixel of FIG. 1. FIG. 3 is a cross-sectional view taken along a line III-III′ of FIG. 1, schematically illustrating a cross-sectional structure of a subpixel.

In general, the light emitting display device 10 according to example embodiments of the present disclosure may include any one of all types of display devices that display images with light emitting diodes OD which are self-luminous elements.

In this example embodiment discussed below, for the convenience of explanation, an organic light emitting display device is taken as an example as the light emitting display device 10.

In addition, the light emitting display device 10 may be a top emission type or bottom emission type display device. In this embodiment, for the convenience of explanation, a top emission type light emitting display device 10 is taken as an example.

As shown in FIGS. 1 to 3, in the light emitting display device 10 (or a light emitting display panel of the light emitting display device 10) of the present embodiment, a display region AA for displaying an image and a non-display region NA arranged around the display region AA may be defined.

The display region AA may include a plurality of subpixels SP arranged along a plurality of row lines (or horizontal lines) and a plurality of column lines (or vertical lines) on a substrate 101.

Meanwhile, a plurality of gate lines (or scan lines) extending along a row direction (or horizontal direction or first direction) and a plurality of data lines extending along a column direction (or vertical direction or second direction) may be formed on the substrate 101. Each subpixel SP may be connected to the corresponding gate line and data line.

In addition, a power line for transmitting a high-potential driving voltage and a power line for transmitting a low-potential driving voltage may be formed on the substrate 101. The high-potential driving voltage and low-potential driving voltage are applied to the subpixel SP, and during a light emitting period, a light emitting current is applied to the light emitting diode OD of the subpixel SP, so that light emitting operation can be performed.

The plurality of subpixels SP formed on the substrate 101 may include subpixels SP of different colors that constitute a pixel P which is a unit for displaying a color image. In this regard, for example, the plurality of subpixels SP constituting the pixel P may include R, G, and B subpixels (or first, second, and third subpixels) SPr, SPg and SPb that respectively display first, second, and third colors, for example, red (R), green (G), and blue (B). As another example, the plurality of subpixels SP constituting the pixel P may further include a W subpixel that displays white.

In this embodiment, a case where the pixel P is configured with R, G, and B subpixels SPr, SPg, and SPb is taken as an example.

The R, G, and B subpixels SPr, SPg, and SPb may be arranged in various forms. For example, as shown in FIG. 1, the subpixels SP may be arranged in a stripe type in which the subpixels SP of the same color are arranged along the column direction, and the subpixels SP of different colors are arranged alternately and repeatedly along the row direction, but not limited thereto.

Meanwhile, in the light emitting display device 10 of this embodiment, an anode 150 is formed after a bank 160 is formed, and an edge of the anode 150 may be formed on the bank 160 along a surface of the bank 160.

A light emitting layer 165 may be formed on the anode 150 and substantially disposed on an inside of the anode 150, so that an end portion AE2e of the anode 150 may have a shape that extends (or protrudes) outside the light emitting layer 165.

In addition, edges of the anode 150 and the light emitting layer 165 may be covered by a high-resistance protective pattern PP. By the high-resistance protective pattern PP, the anode 150 may be substantially electrically insulated from surrounding conductive elements.

According to planar and cross-sectional arrangement structures of the bank 160, the anode 150, the light emitting layer 165, and the high-resistance protective pattern PP, deterioration progress in an inner direction of the light emitting layer 165 may be reduced or prevented, thereby reducing or preventing shrinkage of a light emission region EA. In addition, a short circuit between the anode 150 and a cathode 169 may be structurally prevented. In addition, a lateral leakage current between adjacent subpixels SP may be structurally prevented. Furthermore, luminance deviation according to position within the subpixel SP may be improved.

The structure of the subpixel SP of the present embodiment that can realize the above advantages is described in more detail below with reference to FIGS. 1 to 3. Meanwhile, in FIG. 3, for convenience of explanation, one thin film transistor T formed in the R subpixel SPr is illustrated as an example, and the thin film transistor T is omitted in the G and B subpixels SPg and SPb.

As shown in FIGS. 1 to 3, in each subpixel SP, a subpixel driving circuit including the thin film transistor T, and the light emitting diode OD may be formed on the substrate 101. Meanwhile, a plurality of thin film transistors including the thin film transistor T may be formed in the subpixel driving circuit of each subpixel SP, and at least one capacitor may be further formed in the subpixel driving circuit of each subpixel SP.

In more detail, a semiconductor layer 112 may be formed on the substrate 101. The semiconductor layer 112 may be formed of amorphous silicon, polycrystalline silicon, or an oxide semiconductor material, but not limited thereto.

The semiconductor layer 112 may include a central channel region and source and drain regions on both sides thereof.

Meanwhile, a buffer layer 105 may be formed on the substrate 101 and below the semiconductor layer 112.

A gate insulating layer 115 may be formed as an insulating layer made of an insulating material on the semiconductor layer 112. The gate insulating layer 115 may be formed of an inorganic insulating material such as silicon oxide or silicon nitride, but not limited thereto.

A gate electrode 120 formed of a conductive material such as metal may be formed on the gate insulating layer 115 corresponding to the channel region of the semiconductor layer 112.

In addition, a gate line connected to a gate electrode of a switching thin film transistor may be formed on the gate insulating layer 115.

An interlayered insulating layer 125 may be formed as an insulating layer made of an insulating material on the gate electrode 120 and the gate line.

The interlayered insulating layer 125 may be formed of an inorganic insulating material such as silicon oxide or silicon nitride, or an organic insulating material such as benzocyclobutene or photo acrylic, but not limited thereto.

The interlayered insulating layer 125 and the gate insulating layer 115 therebelow may include a first semiconductor contact hole CHs1 and a second semiconductor contact hole CHs2 that expose the source region and the drain region of the semiconductor layer 112, respectively.

The first semiconductor contact hole CHs1 and the second semiconductor contact hole CHs2 may be positioned on both sides of the gate electrode 120 and spaced apart from the gate electrode 120.

A source electrode 131 and a drain electrode 133 made of a conductive material such as a metal may be formed on the interlayered insulating layer 125.

In addition, a data line that intersects the gate line GL and is connected to a source electrode of the switching thin film transistor may be formed on the interlayered insulating layer 125.

The source electrode 131 and the drain electrode 133 may be positioned spaced apart from each other with respect to the gate electrode 120 and contact the source region and the drain region of the semiconductor layer 112 through the first semiconductor contact hole CHs1 and the second semiconductor contact hole CHs2, respectively.

The semiconductor layer 112, the gate electrode 120, the source electrode 131, and the drain electrode 133 configured as described above can form the thin film transistor T.

As another example, the thin film transistor T may have an inverted staggered structure in which the gate electrode 120 is positioned below the semiconductor layer 112, and the source electrode 131 and the drain electrode 133 are positioned over the semiconductor layer 112. An overcoat layer (or passivation layer) 135 formed of an insulating material may be formed on the source electrode 131, the drain electrode 133, and the data line.

The overcoat layer 135 may be formed by including at least one of an inorganic insulating material such as silicon oxide or silicon nitride, and an organic insulating material such as benzocyclobutene or photo acrylic, but not limited thereto. The overcoat layer 135 may be formed in a single-layered structure or a multi-layered structure.

A drain contact hole CHd exposing the drain electrode 133 may be formed in the overcoat layer 135.

Meanwhile, the overcoat layer 135 may have an upper surface (or top surface) having, for example, a substantially flat shape. Accordingly, the light emitting diode OD disposed in the light emission region EA may have a substantially flat shape, so that the subpixel SP can implement uniform light emission characteristics. On the overcoat layer 135, a bank 160 may be formed along a boundary of each subpixel SP (or boundary between adjacent subpixels SP).

The bank 160 may be formed of, for example, at least one of an acrylic resin, an epoxy resin, a phenol resin, a polyamide-based resin, a polyimide-based resin, an unsaturated polyester-based resin, a polyphenylene-based resin, a polyphenylene sulfide-based resin, benzocyclobutene, and a photoresist, but not limited thereto.

The bank 160 may have a first opening OP1 for defining the light emission region EA in which light emission occurs within each subpixel SP. As described later, the light emission region EA of the subpixel SP may be defined in correspondence with a second opening OP2 within the high-resistance protective pattern PP. Accordingly, the first opening OP1 may be a space for setting an effective light emission region EA inside it.

A portion of the overcoat layer 135 corresponding to the first opening OP1 of the bank 160 may be exposed upward through the first opening OP1.

On the substrate 101 on which the bank 160 is formed, the anode (or first electrode) 150 may be formed for each subpixel SP.

In this regard, the anode 150 of the subpixel SP may be substantially formed integrally within the subpixel SP, and may be formed in a continuous form within the subpixel SP. The anode 150 may be physically separated and spaced from the anode 150 of the neighboring subpixel SP.

The anode 150 may be in contact with the drain electrode 133 through the drain contact hole CHd.

The anode 150 may have high reflective characteristics by including an opaque metal material when the light emitting display device 10 is a top emission type. For example, the anode 150 may include one of Ag, Al, Mo, Ti, and APC (Al—Pd—Cu) alloy, but not limited thereto.

Meanwhile, the anode 150 may be formed in a multi-layered structure. In this regard, for example, the anode 150 may be formed in a multi-layered structure in which a transparent conductive material (e.g., ITO, IZO, IZTO, etc.) is laminated on and/or below the above-described opaque metal material.

As another example, when the light emitting display device 10 is a bottom emission type, the anode 150 may include a transparent electrode layer and may not have a reflective layer.

As described above, in this embodiment, the anode 150 may be formed after forming the bank 160. The anode 150 fills the first opening OP1 of the bank 160, and its edge may be formed on the surface of the bank 160, for example, the side surface and the upper surface.

A flat portion of the anode 150 that contacts the upper surface of the overcoat layer 135 within the first opening OP1 may be referred to as a first portion AE1, and a portion of the anode 150 formed along the surface of the bank 160 as an edge portion located outside the first portion AE1 may be referred to as a second portion AE2.

On the substrate 101 on which the anode 150 is formed, the light emitting layer 165 having an area substantially smaller than that of the anode 150 may be formed.

In this regard, a side end (or side surface) of the light emitting layer 165 may be located inside a side end of the anode 150. In other words, the light emitting layer 165 may be formed within a region where the anode 150 is formed.

Accordingly, the light emitting layer 165 may be formed so as not to cover the end portion AE2e of the anode 150 (or the end portion AE2e of the second portion AE2) (or not to overlap with the end portion AE2e). In other words, the end portion AE2e of the second portion AE2 of the anode 150 located on the upper surface of the bank 160 may have a protruding shape that extends to the outside of the light-emitting layer (165).

Accordingly, the end portion AE2e of the anode 150 may be exposed without being covered by the light emitting layer 165.

As such, in this embodiment, within the subpixel SP, the anode 150 may be formed on the bank 160, and the light emitting layer 165 on the anode 150 may be formed with a smaller area than the anode 150, so that the end portion AE2e of the anode 150 may be exposed.

According to the above stacking and arrangement structure, the anode 150 is exposed around the light emitting layer 165, so that foreign substances that act as deterioration factors, such as gas or moisture, can be released to an outside through the end portion AE2e in the exposed state. Accordingly, deterioration of the light emitting layer 165 caused by gas or moisture can be effectively reduced (or delayed) or prevented.

In this regard, in the conventional light emitting display device, the bank 160 covers the edge of the anode 150, and the light emitting layer 165 is formed on the anode 150 and the bank 160. In this structure, gas or moisture is not released to an outside but remains at a region where the anode 150, the bank 160, and the light emitting layer 165 meet, and this causes the light emitting layer 165 to deteriorate inward.

On the other hand, according to this embodiment, the anode 150 is formed on the bank 160 and the light emitting layer 165 is formed with a smaller area than the anode 150, so that the anode 150 can have a structure in which the end portion AE2e is exposed. Accordingly, foreign substances acting as deterioration factors can be effectively released to the outside when a baking process, etc., is performed, thereby reducing or preventing deterioration of the light emitting layer 165. As a result, the phenomenon of shrinkage of the light emission region EA due to deterioration in the inward direction can be effectively improved.

Meanwhile, the light emitting layer 165 may be formed for each subpixel SP, similar to the anode 150. In other words, the light emitting layer 165 of the subpixel SP may be substantially formed integrally within the subpixel SP, and may be continuously formed within the subpixel SP while being in contact with the anode 150. The light emitting layer 165 may be physically separated and spaced from the light emitting layer 165 of the neighboring subpixel SP.

On the substrate 101 on which the light emitting layer 165 is formed, the high-resistance protective pattern PP may be formed along the edge (or boundary) of each subpixel SP.

The high-resistance protective pattern PP may be formed to cover the edges of the light emitting layer 165 and the anode 150.

For example, the high-resistance protective pattern PP may have the second opening OP2 therein exposing the light emitting layer 165, and the second opening OP2 may be located within the first opening OP1 and may have a size (or area) equal to or smaller than that of the first opening OP1. Preferably, the second opening OP2 of the high-resistance protective pattern PP may be formed to have a size smaller than that of the first opening OP1 of the bank 150.

As such, the light emitting layer 165 may be exposed upward through the second opening OP2 of the high-resistance protective pattern PP and come into contact with the cathode 169. Thus, the second opening OP2 of the high-resistance protective pattern PP can define the light emission region EA where actual light emission action occurs.

The high-resistance protective pattern PP may have substantially insulating property, for example, by having a high resistance of 10¹² ohms or more. In this regard, the high-resistance protective pattern PP may be formed of an inorganic insulating material such as silicon oxide or silicon nitride, or a transparent metal oxide (e.g., IZO, ITO, IZO, etc.) containing a high concentration of oxygen to implement a high resistance of 10¹² ohms or more.

The high-resistance protective pattern PP may be formed to cover the second portion AE2 which is the edge portion of the anode 150, and the edge portion of the light emitting layer 165 located on the second portion AE2, so as to cover and protect the end portion AE2e of the anode 150 exposed outside the light emitting layer 165.

Accordingly, corresponding to the second opening OP2 of the protection pattern PP, the first portion AE1 of the anode 150 having a substantially flat shape and a flat portion of the light emitting layer 165 positioned on the first portion AE1 may be positioned.

Meanwhile, the protection pattern PP may be formed, for example, for each subpixel SP. In this regard, the protection pattern PP may be formed in a shape that surrounds the light emission region EA of the subpixel SP. In this case, the protection pattern PP of each subpixel SP may be spaced apart from the protection pattern PP of the neighboring subpixel SP by a certain distance, and the upper surface of the bank 160 may be exposed upward in the spaced region between the high-resistance protective patterns PP.

The cathode (or second electrode) 169 may be formed on the substrate 101 on which the high-resistance protection pattern PP is formed. The cathode 169 may be formed, for example, integrally over the entire surface of the substrate 101. In other words, the cathode 169 may be formed continuously along the plurality of subpixels SP. In this case, the cathode 169 may be formed along over the light emitting layer 169 in the second opening OP2 of the high-resistance protective pattern PP, the high-resistance protective pattern PP, and the bank 160 between the adjacent high-resistance protective patterns PP.

As another example, the cathode 169 may be formed for each subpixel SP so as to be physically separated and spaced from the cathode 169 of the adjacent subpixel SP.

The cathode 169 may include a transparent electrode layer made of a transparent conductive material (e.g., ITO, IZO, IZTO, etc.) when the light emitting display device 10 is a top emission type. As another example, when the light emitting display device 10 is a bottom emission type, the cathode 169 may include a reflective layer formed of metal.

The anode 150, the light emitting layer 165, and the cathode 169 arranged as described above in the second opening OP2 in each subpixel SP may constitute the light emitting diode OD.

The light emitting diode OD emits light from the light emitting layer 165 interposed between the anode 150 and the cathode 169, and the light emitted may travel upward and be output.

The anode 150, the light emitting layer 165, and the cathode 169 arranged in the second opening OP2 of each subpixel SP, i.e., arranged in the light emission region EA have a substantially flat shape. Accordingly, the light emitting diode OD formed in the emission region EA has a substantially uniform (or constant) thickness, so that uniform luminance characteristics can be implemented regardless of position.

In this regard, in the conventional light emitting display device mentioned above, the light emitting layer 165 is deposited with a relatively thin thickness on a portion the bank 165 covering the edge of the anode 150, so that a light emission luminance is higher at this position than inside, resulting in luminance deviation within the light emission region EA.

On the other hand, according to this embodiment, the light emitting diode OD (or its light emitting layer 165) has a substantially uniform (or constant) thickness in the light emission region EA defined in the second opening OP2, so that the luminance deviation within the light emission region EA can be improved, and uniformity of luminance can be secured.

In addition, as mentioned above, the high-resistance protective pattern PP can cover and protect the edge of the anode 150. Accordingly, the cathode 169 formed on the high-resistance protective pattern PP is structurally insulated from the anode 150, so that a short circuit between the anode 150 and the cathode 169 can be prevented.

In addition, since the high-resistance protective pattern PP covers the edge of the anode 150, the anode 150 is structurally insulated from the anode 150 of the neighboring subpixel SP. Accordingly, lateral leakage current between the neighboring subpixels SP can be reduced or prevented.

Hereinafter, a method of manufacturing the light emitting display device of this embodiment having the above-described structure is described in more detail.

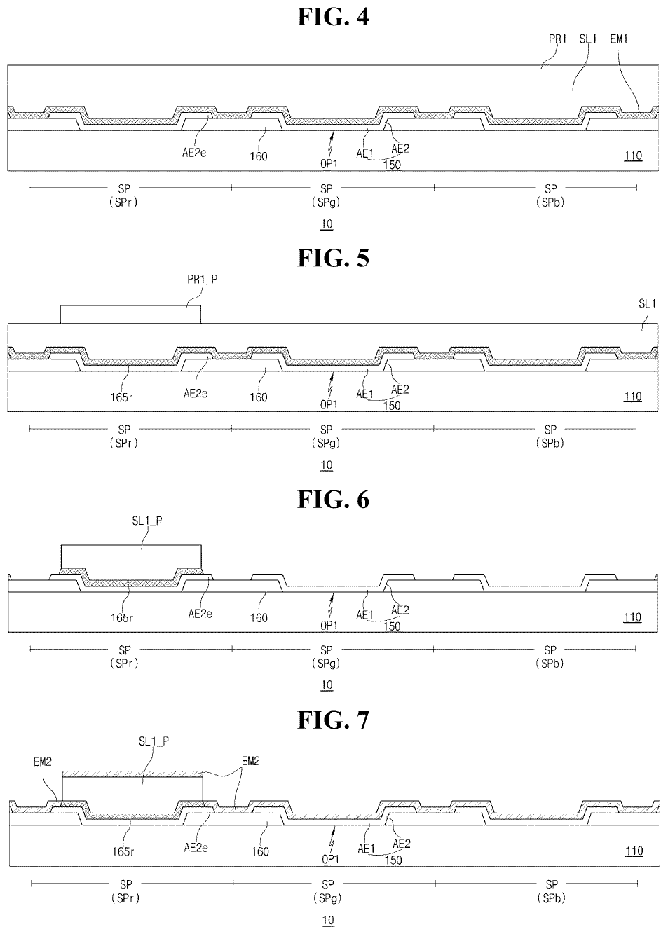

FIGS. 4 to 23 are views schematically illustrating a method of manufacturing a light emitting display device according to an embodiment of the present disclosure, and illustrate processes of forming the light emitting layer 165, the high-resistance protective pattern PP, and the cathode 169. Meanwhile, in FIGS. 4 to 23, for convenience of explanation, layers laminated below the bank 160 and the anode 150 are omitted.

First, as shown in FIG. 4, a first light emitting material may be deposited over the entire surface of the substrate 101, on which the bank 160 and the anode 150 are formed (or at least over the entire surface of the display region of the substrate 101), to form a first light emitting material layer EM1. The first light emitting material is for forming, for example, an R light emitting layer (or first light emitting layer) which is a light emitting layer of the R subpixel SPr.

Next, a first protective layer SL1 and a first PR (photoresist) layer PR1 may be formed (or coated) on the first light emitting material layer EM1. The first protective layer SL1 may serve as a layer for protecting the first light emitting material layer EM1 in a subsequent etching process. The first protective layer SL1 may be formed of, for example, a polymer, and more preferably, may be formed of a fluorine-based polymer having excellent moisture-proof property, but not limited thereto.

Next, as shown in FIG. 5, light-exposure and development process may be performed to form a first PR pattern PR1_P corresponding to the R subpixel SPr. For example, the first PR pattern PR1_P may correspond to the anode 150 of the R subpixel SPr and may be formed to have a smaller size (or area) than the anode 150 of the R subpixel SPr.

Next, as shown in FIG. 6, an etching process (e.g., a dry etching process) may be performed to etch the first protective layer SL1 and the first light emitting material layer EM1. Accordingly, an R light emitting layer 165r having a smaller size than the anode 150 of the R subpixel SPr may be formed.

In addition, a first protective layer pattern SL1_P having substantially the same shape as the R light emitting layer 165r may be formed on the R light emitting layer 165r through the etching process.

In the etching process, the anode 150 and the bank 160 located below the R light emitting layer 165r may function as an etch stopper.

Meanwhile, during the etching process, the first PR pattern PR1_P may be etched and removed. As another example, a strip process may be performed to remove the first PR pattern PR1_P after the etching process.

Next, as shown in FIG. 7, a second light emitting material may be deposited over the entire surface of the substrate 101, on which the R light emitting layer 165r and the first protective layer pattern SL1_P are formed, to form a second light emitting material layer EM2. The second light emitting material is for forming, for example, a G light emitting layer (or second light emitting layer) which is a light emitting layer of the G subpixel SPg.

The second light emitting material layer EM2 may also be deposited on the first protective layer pattern SL1_P.

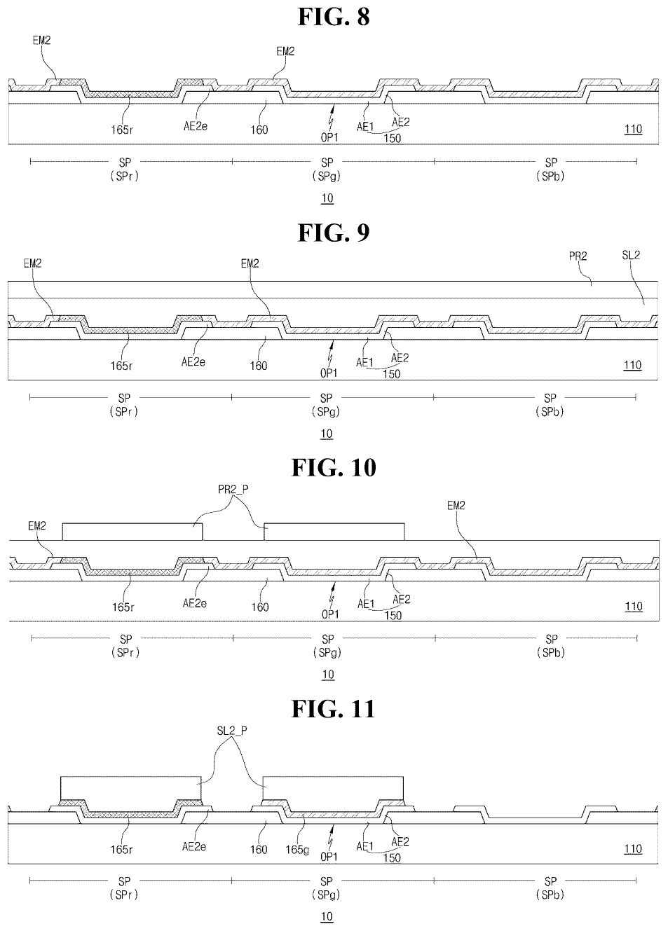

Next, as shown in FIG. 8, a strip process (or lift-off process) may be performed to remove the first protective layer pattern SL1_P. Accordingly, a portion of the second light emitting material layer EM2 deposited on the first protective layer pattern SL1_P may also be removed.

Next, as shown in FIG. 9, a second protective layer SL2 and a second PR layer PR2 may be formed over the substrate 101 on which the second light emitting material layer EM2 is formed. The second protective layer SL2 may be formed of the same material as the first protective layer SL1.

Next, as shown in FIG. 10, light-exposure and development process may be performed to form a second PR pattern PR2_P corresponding to each of the R subpixel SPr and the G subpixel SPg. The second PR pattern PR2_P may be formed, for example, with substantially the same size as the first PR pattern PR1_P. That is, the second PR pattern PR2_P may correspond to the anode 150 of each of the R and G subpixels SPr and SPg and be formed to have a size (or area) smaller than that of the anode 150 of each of the R and G subpixels SPr and SPg.

The second PR pattern PR2_P located on the R subpixel SPr may be formed to have a size substantially corresponding to the R light emitting layer 165r therebelow.

Next, as shown in FIG. 11, an etching process (e.g., a dry etching process) may be performed to etch the second protective layer SL2 and the second light emitting material layer EM2. Accordingly, a G light emitting layer 165g having a size smaller than that of the anode 150 of the G subpixel SPg may be formed on the anode 150 of the G subpixel SPg.

In addition, a second protective layer pattern SL2_P having substantially the same shape as the G light emitting layer 165g may be formed on the G light emitting layer 165g by the etching process. In addition, the second protective layer pattern SL2_P having substantially the same shape as the R light emitting layer 165r may be formed on the R light emitting layer 165r, and the R light emitting layer 165r may maintain its shape without being substantially etched.

In the etching process, the anode 150 and bank 160 located below the G and R light emitting layers 165g and 165r may function as an etch stopper.

Meanwhile, during the etching process, the second PR pattern PR2_P may be etched and removed. As another example, a strip process for removing the second PR pattern PR2_P after the etching process may be performed.

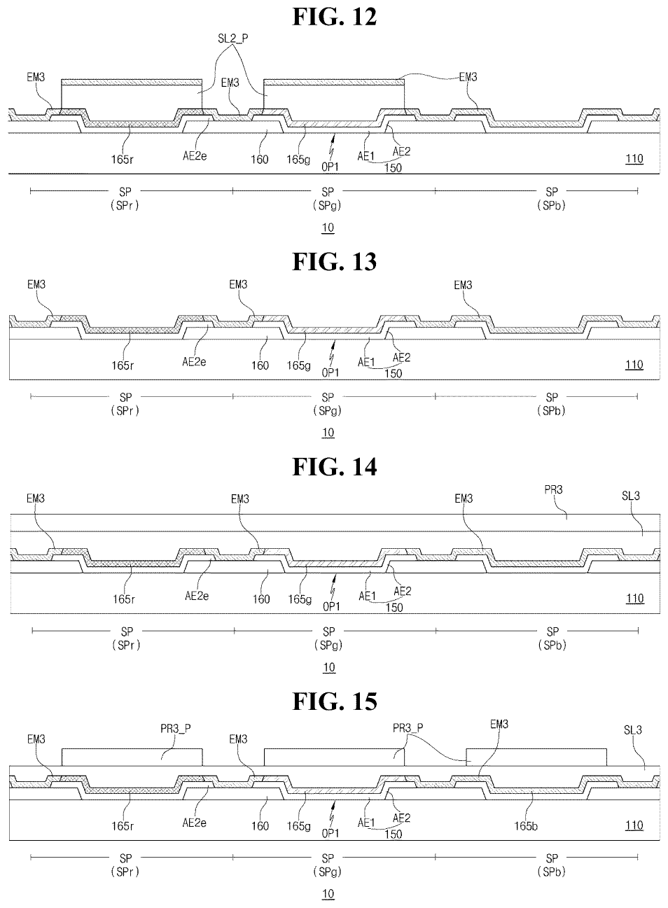

Next, as shown in FIG. 12, a third light emitting material may be deposited over the entire surface of the substrate 101, on which the G and R light emitting layers 165g and 165r and the second protective layer pattern SL2_P are formed, to form a third light emitting material layer EM3. The third light emitting material is, for example, for forming a B light emitting layer (or third light emitting layer) which is a light emitting layer of the B subpixel SPb.

The third light emitting material layer EM3 may also be deposited on the second protective layer pattern SL2_P.

Next, as shown in FIG. 13, the second protective layer pattern SL2_P may be removed by performing a strip process (or lift-off process). Accordingly, the third light emitting material layer EM3 deposited on the second protective layer pattern SL2_P may also be removed.

Next, as shown in FIG. 14, a third protective layer SL3 and a third PR layer PR3 may be formed over the substrate 101 on which the third light emitting material layer EM3 is formed. The third protective layer SL3 may be formed of the same material as the first and second protective layers SL1 and SL2.

Next, as shown in FIG. 15, by performing light-exposure and development process, a third PR pattern PR3_P corresponding to each of the R subpixel SPr, the G subpixel SPg, and the B subpixel SPb may be formed. For example, the third PR pattern PR3_P may be formed to have substantially the same size as the first and second PR patterns PR1_P and PR2_P. That is, the third PR pattern PR3_P may correspond to the anode 150 of each of the R, G, and B subpixels SPr, SPg, and SPb and be formed to have a size (or area) smaller than that of the anode 150 of each of the R, G, and B subpixels SPr, SPg, and SPb.

The third PR pattern PR3_P positioned on each of the R and G subpixels SPr and SPg may be formed to have a size substantially corresponding to each of the R and G light emitting layers 165r and 165g.

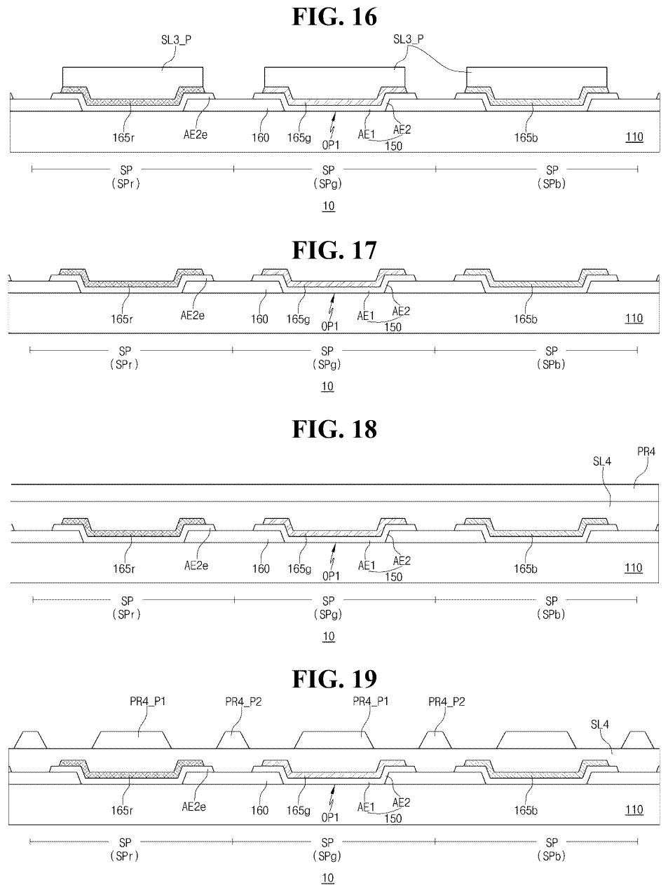

Next, as shown in FIG. 16, an etching process (e.g., a dry etching process) may be performed to etch the third protective layer SL3 and the third light emitting material layer EM3. Accordingly, a B light emitting layer 165b having a smaller size than the anode 150 of the B subpixel SPb may be formed on the anode 150 of the B subpixel SPb.

In addition, a third protective layer pattern SL3_P having substantially the same shape as the B light emitting layer 165b may be formed on the B light emitting layer 165b by the etching process. In addition, the third protective layer pattern SL3_P having substantially the same shape as each of the R and G light emitting layers 165r and 165g may be formed on each of the R and G light emitting layers 165r and 165g, and the R and G light emitting layers 165r and 165g may not be substantially etched and may maintain their shape.

In the etching process, the anode 150 and the bank 160 located below the B, G, and R light emitting layers 165b, 165g, and 165r may function as etch stoppers.

Meanwhile, during the etching process, the third PR pattern PR3_P may be etched and removed. As another example, a strip process may be performed to remove the third PR pattern PR3_P after the etching process.

Next, as shown in FIG. 17, a strip process may be performed to remove the third protective layer pattern SL3_P.

Through the above processes, the R, G, and B light emitting layers 165r, 165g, and 165b each having a smaller size than the anode 150 may be formed on the anodes 150 in the R, G, and B subpixels SPr, SPg, and SPb, respectively.

Next, as shown in FIG. 18, a fourth protective layer SLA and a fourth PR layer PR4 may be formed over the substrate 101 on which the R, G, and B light emitting layers 165r, 165g, and 165b are formed. The fourth protective layer SL4 may be formed of the same material as the first to third protective layers SL1 to SL3.

Next, as shown in FIG. 19, by performing light-exposure and development process, a fourth PR pattern (or fourth, first PR pattern) PR4_P1 corresponding to each of the R, G, and B subpixels SPr, SPg, and SPb, more specifically, each of the R, G, and B light emitting layers 165r, 165g, and 165b may be formed. In addition, a fifth PR pattern (or fourth, second PR pattern) PR4_P2 corresponding to the boundary between the R, G, and B subpixels SPr, SPg, and SPb may be formed.

In this case, the fifth PR pattern PR4_P2 may be formed to be spaced apart from its adjacent fourth PR pattern PR4_P1 by a certain distance.

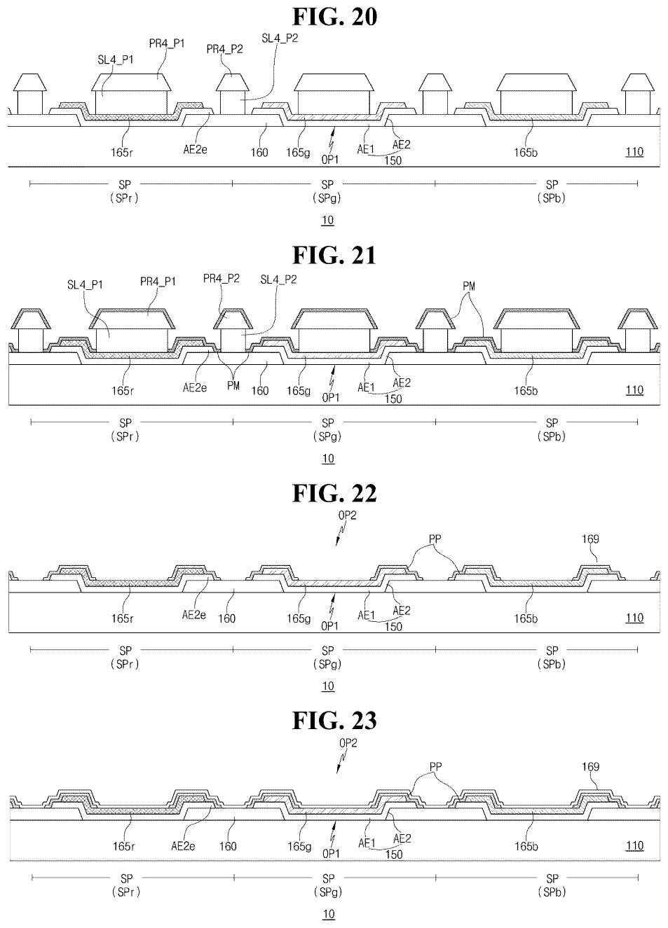

Next, as shown in FIG. 20, an etching process (e.g., a dry or wet etching process) may be performed to etch the fourth protective layer SL4. In this regard, an over-etching may be performed for the fourth protective layer SLA, so that the fourth protective layer SL4 may be etched further inward than the fourth and fifth PR patterns PR4_P1 and PR4_P2.

Accordingly, fourth and fifth protective layer pattern (or fourth, first and fourth, second protective layer patterns) SLA_P1 and SL4_P2 may be respectively formed under the fourth and fifth PR patterns PR4_P1 and PR4_P2 that are recessed further inward.

As such, the fourth and fifth protective layer patterns SLA_P1 and SLA_P2 are formed to have smaller areas by being recessed inwardly than the fourth and fifth PR patterns PR4_P1 and PR4_P2, respectively, so that the fourth PR pattern PR4_P1 and the fourth protective layer pattern SLA_P1 have an undercut structure, and the fifth PR pattern PR4_P2 and the fifth protective layer pattern SLA_P2 have an undercut structure.

Next, as shown in FIG. 21, a high-resistance protective material may be deposited over the substrate 101, on which the fourth and fifth protective layer patterns SL4_P1 and SLA_P2 are formed, to form a protective material layer PM. The protective material is for forming the high-resistance protective pattern PP located at the edge of each subpixel SP.

The protective material layer PM may be deposited on the fourth and fifth PR patterns PR4_P1 and PR4_P2. In addition, the protective material layer PM may be formed on the anode 150 and the R, G, and B light emitting layers 165r, 165g, and 165b located at the edge of each subpixel SP which is a spaced region between the fourth and fifth protective layer patterns SLA_P1 and SLA_P2.

Next, as shown in FIG. 22, the fourth and fifth protective layer patterns SL4_P1 and SLA_P2 may be removed by performing a strip process (or lift-off process). Accordingly, the fourth and fifth PR patterns PR4_P1 and PR4_P2 formed on the fourth and fifth protective layer patterns SLA_P1 and SLA_P2 and the protective material layer PM thereon may also be removed together.

Through the strip process, the protective material layer PM formed along the edge of each subpixel SP may remain in a pattern shape on the substrate 101 to form the high-resistance protective pattern PP.

Through the processes described above, the high-resistance protective pattern PP covering the edge of the anode 150 and the R, G, and B light emitting layer 165r, 165g, or 165b of each subpixel SP may be formed.

Next, as shown in FIG. 23, a cathode material may be deposited over the substrate 101, on which the high-resistance protective pattern PP is formed, to form the cathode 169.

By performing the processes described above, the light emitting diode OD according to the present embodiment may be formed.

As described above, according to the embodiment of the present disclosure, in the subpixel, the anode is formed on the bank, and the light emitting layer on the anode is formed with a smaller area than the anode, so that the end portion of the anode is not covered by the light emitting layer.

Accordingly, foreign substances acting as deterioration factors can be discharged to the outside, so that deterioration of the light emitting layer can be reduced or prevented, and as a result, the phenomenon of shrinkage of the light emission region due to deterioration progressing in the inward direction can be effectively improved.

In addition, the edges of the anode and the light emitting layer can be covered by the high-resistance protective pattern.

Accordingly, since the light emitting diode has a substantially uniform thickness in the light emission region defined in the opening inside the high-resistance protective pattern, the luminance deviation within the light emission region can be improved, so that the luminance uniformity can be secured.

In addition, since the cathode is structurally insulated from the anode by the high-resistance protective pattern, a short circuit between the anode and the cathode can be prevented.

Moreover, since the anode is structurally insulated from the anode of the neighboring subpixel by the high-resistance protective pattern, lateral leakage current between the neighboring subpixels can be reduced or prevented.

It will be apparent to those skilled in the art that various modifications and variation can be made in the present disclosure without departing from the spirit or scope of the disclosure. Thus, it is intended that the present disclosure cover the modifications and variations of this disclosure provided they come within the scope of the appended claims and their equivalents.

What is claimed is:

1. A light emitting display device, comprising:
a substrate including a plurality of subpixels;
a bank formed along a boundary of a subpixel, among the plurality of subpixels, the bank including a first opening;
a first electrode in the first opening and on the bank;
a light emitting layer on the first electrode and disposed inside the first electrode;
a protective pattern which has an insulating property, covers edges of the first electrode and the light emitting layer, and includes a second opening corresponding to the first opening; and
a second electrode in the second opening and on the protective pattern.

2. The light emitting display device of claim 1, wherein an end portion of the edge of the first electrode has a shape that protrudes outward from the light emitting layer and is covered by the protective pattern.

3. The light emitting display device of claim 1, wherein the second opening has a smaller area than the first opening.

4. The light emitting display device of claim 1, wherein the first electrode, the light emitting layer, and the second electrode located in the second opening have a uniform thickness.

5. The light emitting display device of claim 1, wherein the protective pattern disposed at an edge of the subpixel is spaced apart from the protective pattern of an adjacent subpixel among the plurality of subpixels.

6. The light emitting display device of claim 1, wherein the protective pattern has a resistance of 10¹² ohms or more.

7. The light emitting display device of claim 6, wherein the protective pattern includes an inorganic insulating material or a transparent metal oxide.

8. A method of manufacturing a light emitting display device, comprising:
forming a bank on a substrate including a plurality of subpixels, the bank being arranged along a boundary of a subpixel, among the plurality of subpixels, and including a first opening;
forming a first electrode in the first opening and on the bank;
forming a light emitting layer on the first electrode and inside the first electrode;
forming a protective pattern having an insulating property, covering edges of the first electrode and the light emitting layer, and including a second opening corresponding to the first opening; and
forming a second electrode in the second opening and on the protective pattern.

9. The method of claim 8, wherein forming the protective pattern includes:
forming a protective layer and a photoresist layer over the substrate on which the light emitting layer is formed;
light-exposing and developing the photoresist layer to form a first photoresist pattern corresponding to the light emitting layer and a second photoresist pattern corresponding to a boundary between the subpixel and an adjacent subpixel, among the plurality of subpixels;
performing an etching process for the protective layer to form a first protective layer pattern in an undercut shape under the first photoresist pattern and a second protective layer pattern in an undercut shape under the second photoresist pattern;
forming a protective material layer over the substrate on which the first and second protective layer patterns are formed; and
lifting off the first and second protective layer patterns to form the protective pattern which is a protective material layer remaining on the substrate.

10. The method of claim 8, wherein an end portion of the edge of the first electrode has a shape that protrudes outward from the light emitting layer and is covered by the protective pattern.

11. The method of claim 8, wherein the second opening has a smaller area than the first opening.

12. The method of claim 8, wherein the first electrode, the light emitting layer and the second electrode located in the second opening have a uniform thickness.

13. The method of claim 8, wherein the protective pattern disposed at an edge of the subpixel is spaced apart from the protective pattern of an adjacent subpixel among the plurality of subpixels.

14. The method of claim 8, wherein the protective pattern has a resistance of 10¹² ohms or more.

15. The method of claim 14, wherein the protective pattern includes an inorganic insulating material or a transparent metal oxide.
